(19) United States
(12) Patent Application Publication
(10) Pub. No.: US 2025/0165340 A1
(43) Pub. Date: May 22, 2025

(54) SELF-ADAPTATION OF DRAM COMMAND/ADDRESS INTERFACE

(71) Applicant: Micron Technology, Inc., Boise, ID (US)

(72) Inventors: Jennifer E. Taylor, Boise, ID (US); Timothy M. Hollis, Meridian, ID (US); Eric J. Stave, Meridian, ID (US); Chulkyu Lee, Meridian, ID (US); Chris Gregory Holub, Bath, PA (US)

(21) Appl. No.: 18/901,895

(22) Filed: Sep. 30, 2024

Related U.S. Application Data
(60) Provisional application No. 63/601,014, filed on Nov. 20, 2023.

(51) Int. Cl. G06F 11/10

(52) U.S. Cl. CPC G06F 11/1016; G06F 11/1068

(57) ABSTRACT

A decision counter circuit is used in a self-adaptation circuit to apply digital averaging to input signals to obtain adaptive settings of circuit parameters for a memory chip of a memory device during the operation. Individual adaptive settings of the parameters (e.g., impedance, capacitance, equalization parameters) during operation are obtained for each of the memory chips in the memory device. The self-adaptation enables equalization adjustment across temperature and voltage drift.

### CROSS-REFERENCE TO RELATED APPLICATIONS

This application claims priority to U.S. Provisional Application No. 63/601,014, filed Nov. 20, 2023, which is incorporated by reference herein in its entirety.

### BACKGROUND OF THE INVENTION

### Field of the Invention

The present disclosure relates generally to the field of semiconductor memory devices. More specifically, embodiments of the present disclosure relate to a self-adaptation of the command/address interface of a memory device.

### Description of the Related Art

The operational rates of memory devices, including the data rate of a memory device, has been increasing over time. As a side effect of the increase in speed of a memory device, data errors due to distortion may increase. For example, inter-symbol interference between transmitted data whereby previously received data influences the currently received data may occur (e.g., previously received data affects and interferes with subsequently received data). One manner to correct for this interference is through the use of a decision feedback equalizer (DFE) circuit or a continuous time linear equalization (CTLE) circuit, which may be programmed to offset (i.e., undo, mitigate, or offset) the effect of the channel on the transmitted data. However, a memory device may include multiple memory chips, and signals received at each memory chip may be different due to the way that reflections of the signals line up at corresponding inputs of each memory chip and/or the dynamic changing of the signals during operation (e.g., across process, voltage and temperature (PVT) drift).

### BRIEF DESCRIPTION OF THE DRAWINGS

Various aspects of this disclosure may be better understood upon reading the following detailed description and upon reference to the drawings in which:

FIG. 1 is a simplified block diagram illustrating certain features of a memory device, according to an embodiment of the present disclosure;

FIG. 2 is a simplified block diagram illustrating a portion of a command/address (CA) input circuit of the memory device of FIG. 1, according to an embodiment of the present disclosure;

FIG. 3 illustrates a block diagram of an embodiment of the portion of the CA input circuit of FIG. 2, according to an embodiment of the present disclosure;

FIG. 4 illustrates a block diagram of an embodiment of a bit counter block of FIG. 3, according to an embodiment of the present disclosure;

FIG. 5 illustrates a block diagram of another embodiment of the portion of the CA input circuit of FIG. 2, according to an embodiment of the present disclosure;

FIG. 6 illustrates a flow diagram of a method for implementing self-adaptation circuits to determine adaptive values for input voltage levels, according to an embodiment of the present disclosure; and

FIG. 7 illustrates a flow diagram of a method for implementing self-adaptation circuits to determine adaptive values for equalization parameters, according to an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Memory devices exchange data and store the data in memory banks. Each memory bank may include a plurality of memory cells in which data is stored. A group of memory banks may be provided on a memory chip, and a memory device may include multiple memory chips. Signals received at each memory chip may be different due to the way that reflections of the signals line up at corresponding inputs of each memory chip and/or the dynamic changing of the signals during operation (e.g., across process, voltage and temperature (PVT)). Accordingly, in some embodiments, different parameter settings may be desired for the memory chips in the memory device.

To at least partially improve the corrections for distortions of signals, individual adaptive settings of the parameters (e.g., impedance, capacitance, equalization parameters) during operation may be desired for each of the memory chips in the memory device. As discussed below, this self-adaptation may factor in memory environment-specific complications, such as single-ended signaling, bursty data transmission (including related rapid power up and/or power down), relatively poor transistor performance, bi-directional pins, PVT drift, and/or other situations. The self-adaptation may be performed during the operation of the memory device and may not add training time during boot-up.

The current disclosure herein provides systems and methods to perform self-adaptation to obtain adaptive settings of circuit parameters for a memory chip of a memory device during operation. Decision counter circuits may be used in the self-adaptation circuits to apply digital averaging to the input signals to obtain the adaptive settings. In particular, the adaptive values of the input voltage at high level (V_{IH}) (e.g., compared with VrCA) and the input voltage at low level (V_{IL}) (e.g., compared with VrCA) for inputs at the signal pins (e.g., CA<13:0>) of the memory chip may be determined by using the digital averaging method. The adaptive values of V_{IH} and V_{IL} may be used together with the digital averaging method to determine the adaptive equalization (EQ) parameters (e.g., resistance, capacitance, tap bias coefficients) for a decision feedback equalization (DFE) circuit (e.g., 1-tap DFE, multi tap DFE) or a continuous time linear equalization (CTLE) circuit that is used to mitigate the distortion of the signals for the memory chip. For example, the adaptive values of tap bias coefficients may be determined for a DFE circuit, and the adaptive values of resistance and capacitance may be determined for a CTLE circuit.

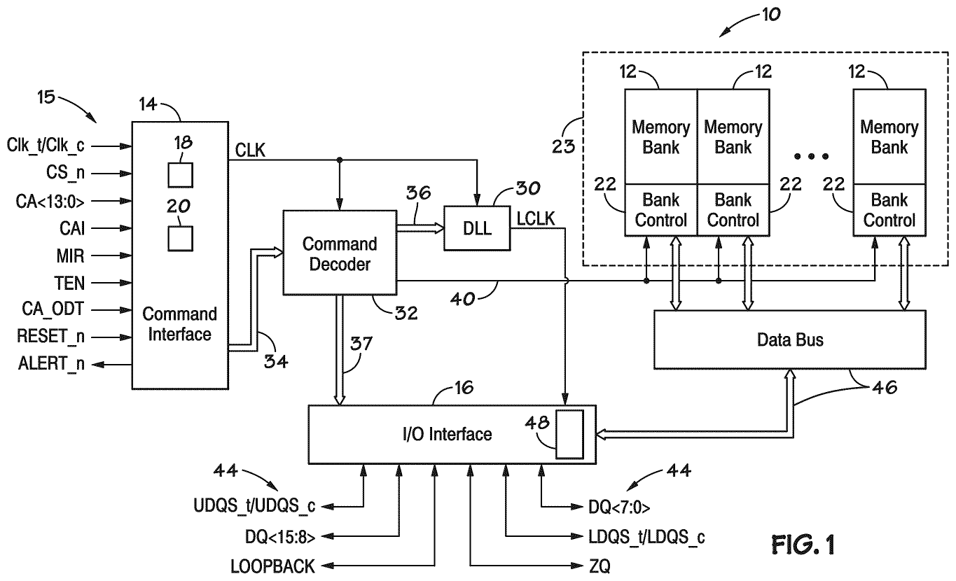

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random access memory (DDR5 SDRAM) device. Various features of DDR5 SDRAM allow for reduced power consumption, more bandwidth and more storage capacity compared to prior generations of DDR SDRAM.

The memory device 10, may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., ×8 or ×16 memory chips), as will be appreciated. Each SDRAM memory chip may include one or more memory banks 12. For DDR5, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 GB DDR5 SDRAM, the memory chip may include 32 memory banks 12 arranged into 8 bank groups with each bank group including 4 memory banks, for instance. Various other configurations, organization and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from an external device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command/address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the complementary clock signal (Clk_c). The positive clock edge for DDR refers to the point where the rising true clock signal Clk_t crosses the falling complementary clock signal Clk_c, while the negative clock edge indicates that transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal CLK. The internal clock signal CLK is supplied to an internal clock generator 30, such as a delay locked loop (DLL) circuit. The internal clock generator 30 generates a phase controlled internal clock signal LCLK based on the received internal clock signal CLK. The phase controlled internal clock signal LCLK is supplied to the I/O interface 16, for instance, and is used as a timing signal for determining an output timing of read data.

The internal clock signal CLK may also be provided to various other components within the memory device 10 and may be used to generate various additional internal clock signals. For instance, the internal clock signal CLK may be provided to a command decoder 32. The command decoder 32 may receive command signals from a command bus 34 and may decode the command signals to provide various internal commands. For instance, the command decoder 32 may provide command signals to the internal clock generator 30 over the bus 36 to coordinate generation of the phase controlled internal clock signal LCLK. The command decoder 32 may also provide command signals to the I/O interface 16 over a bus 37 to facilitate receiving and transmitting I/O signals. The phase controlled internal clock signal LCLK may be used to clock data through the I/O interface 16, for instance.

Further, the command decoder 32 may decode commands received from the command bus 34, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other features, such as timing control and data control, to facilitate the execution of commands to and from the memory banks 12. A group of the memory banks 12 may be included in a memory chip 23, and the memory device 10 may include one or more memory chips.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command/address input circuit 20 in the command interface 14 may be configured to receive and transmit the commands to provide access to the memory banks 12, through the command decoder 32, for instance. In addition, the command interface 14 may receive a chip select signal (CS_n). The chip select signal CS_n enables the memory device 10 to process commands on the incoming command/address signals CA<13:0> for the memory chip selected by the chip select signal CS_n. Accordingly, access to specific banks 12 within the memory device 10 is facilitated by the information encoded on the chip select signal CS_n and the command/address signals CA<13:0>.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over the data bus 46, which includes a plurality of bi-directional data buses. Data I/O signals, generally referred to as DQ signals, are generally transmitted and received in one or more bi-directional data busses. For certain memory devices, such as a DDR5 SDRAM memory device, the I/O signals may be divided into upper and lower bytes. For instance, for an ×16 memory device, the I/O signals may be divided into upper and lower I/O signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the I/O interface 16. The ZQ calibration signal may be provided to a reference pin and used to tune output drivers and on die termination (ODT) values by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the I/O interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description.

In some embodiments, the memory device 10 may be disposed in (physically integrated into or otherwise connected to) a host device or otherwise coupled to a host device. The host device may include any one of a desktop computer, laptop computer, pager, cellular phone, personal organizer, portable audio player, control circuit, camera, etc. The host device may also be a network node, such as a router, a server, or a client (e.g., one of the previously-described types of computers). The host device may be some other sort of electronic device, such as a copier, a scanner, a printer, a game console, a television, a set-top video distribution or recording system, a cable box, a personal digital media player, a factory automation system, an automotive computer system, or a medical device. (The terms used to describe these various examples of systems, like many of the other terms used herein, may share some referents and, as such, should not be construed narrowly in virtue of the other items listed.)

The host device may, thus, be a processor-based device, which may include a processor, such as a microprocessor, that controls the processing of system functions and requests in the host. Further, any host processor may comprise a plurality of processors that share system control. The host processor may be coupled directly or indirectly to additional system elements of the host, such that the host processor controls the operation of the host by executing instructions that may be stored within the host or external to the host.

As discussed above, data may be written to and read from the memory device 10, for example, by the host whereby the memory device 10 operates as volatile memory, such as Double Data Rate DRAM (e.g., DDR5 SDRAM). The host may, in some embodiments, also include separate non-volatile memory, such as read-only memory (ROM), PC-RAM, silicon-oxide-nitride-oxide-silicon (SONOS) memory, metal-oxide-nitride-oxide-silicon (MONOS) memory, polysilicon floating gate based memory, and/or other types of flash memory of various architectures (e.g., NAND memory, NOR memory, etc.) as well as other types of memory devices (e.g., storage), such as solid state drives (SSD's), MultimediaMediaCards (MMC's), SecureDigital (SD) cards, CompactFlash (CF) cards, or any other suitable device. Further, it should be appreciated that the host may include one or more external interfaces, such as Universal Serial Bus (USB), Peripheral Component Interconnect (PCI), PCI Express (PCI-E), Small Computer System Interface (SCSI), IEEE 1394 (Firewire), or any other suitable interface as well as one or more input devices to allow a user to input data into the host, for example, buttons, switching elements, a keyboard, a light pen, a stylus, a mouse, and/or a voice recognition system, for instance. The host may optionally also include an output device, such as a display coupled to the processor and a network interface device, such as a Network Interface Card (NIC), for interfacing with a network, such as the Internet. As will be appreciated, the host may include many other components, depending on the application of the host.

The host may operate to transfer data to the memory device 10 for storage and may read data from the memory device 10 to perform various operations at the host. Accordingly, to facilitate these data transmissions, in some embodiments, the I/O interface 16 may include a data transceiver 48 that operates to receive and transmit DQ signals to and from the I/O interface 16.

As mentioned previously, in some embodiments, the memory device 10 may include more than one memory chips, and the command interface 14 may include a number of signal pins (e.g., CS_n, CA<13:0>, Clk_t/Clk_c, RESET_n) to receive the signals 15 for the memory chips of the memory device 10. The chip select signal (CS_n) may be used to enable the memory device 10 to process commands on the incoming command/address signals CA<13:0> for the memory chip selected by the chip select signal CS_n. However, signals received at each memory chip may be affected by reflections of transmission lines, and the signals may be affected differently due to the way that reflections of the signals lined up at corresponding inputs of each memory chip and/or the dynamic changing of the signals during operation. Accordingly, individual adaptive settings of circuit parameters (e.g., impedance, capacitance, equalization parameters) during operation may be desired for each of the memory chips in the memory device 10.

In some embodiments, a self-adaptation circuit may be used to obtain the adaptive settings of parameters for a memory chip of the memory device 10 during the operation of the memory device 10. A decision counter circuit may be used in the self-adaptation circuit to apply digital averaging to the signals to obtain the adaptive settings, as described in greater detail herein. For instance, the adaptive values of the input voltage at high level (V_{IH}) (e.g., compared with VrCA) and the input voltage at low level (V_{IL}) (e.g., compared with VrCA) for inputs at the signal pins (e.g., CA<13:0>) may be determined by using the digital averaging method. The adaptive values of V_{IH} and V_{IL} may be used together with the digital averaging method to determine the adaptive equalization (EQ) parameters (e.g., resistance, capacitance, tap bias coefficients) for a decision feedback equalization (DFE) circuit or a continuous time linear equalization (CTLE) circuit that is used to mitigate the distortion of the signals for the memory chip.

In some embodiments, each of the signal pins (e.g., CS_n, CA<13:0>, Clk_t/Clk_c) of the command interface 14 may be self-adapted individually since they may be connected to different numbers of memory chips and/or operated at different frequencies. In these embodiments, each of the signal pins of the command interface 14 may have a unique self-adaptation circuit. In some embodiments, common self-adaptation circuitry may be shared within a group of signal pins (e.g., CS_n, CA<13:0>, Clk_t/Clk_c) or within all signal pins of the command interface 14, for the purpose of power saving or area efficiency (AE).

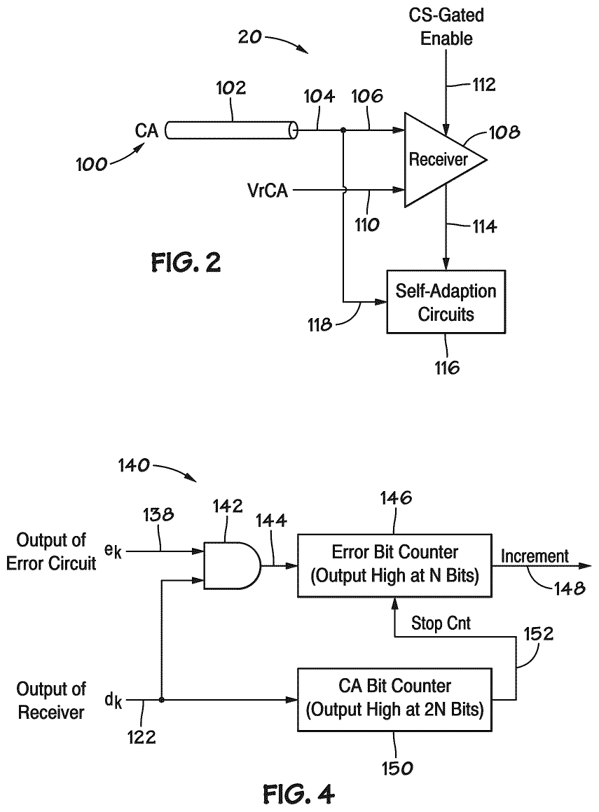

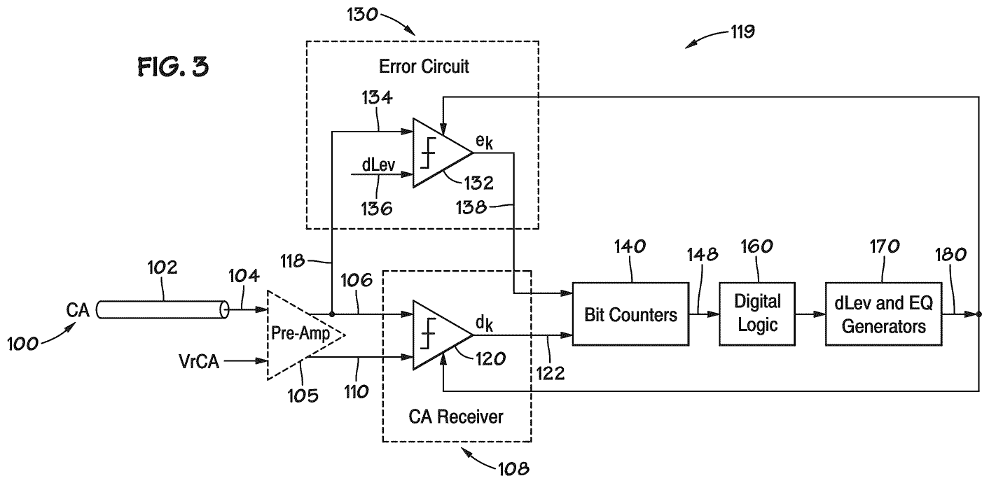

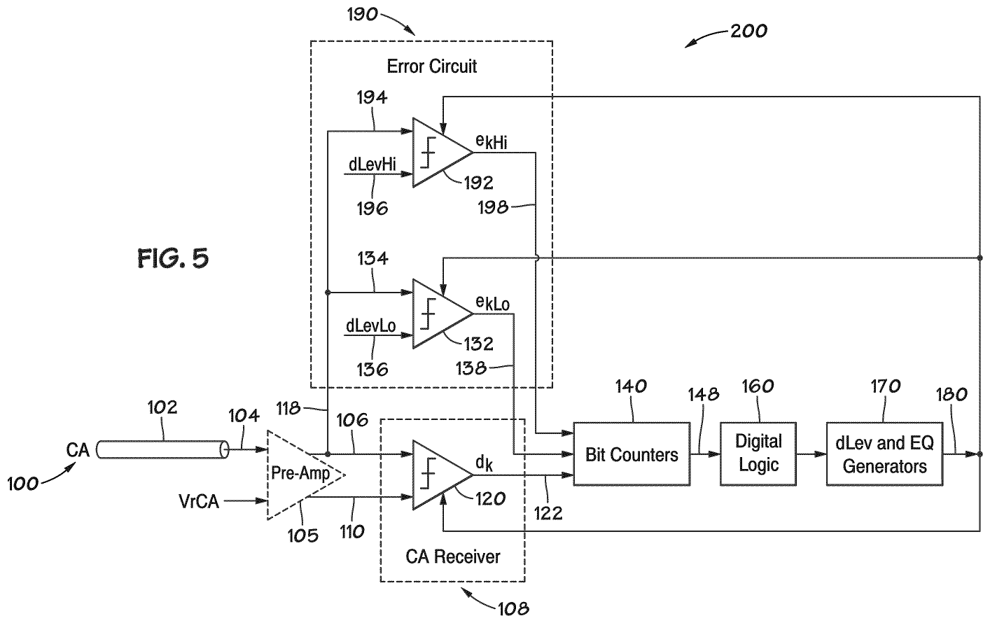

FIG. 2 illustrates an embodiment of a portion of the command/address input circuit 20 of the memory device 10 that includes self-adaptation circuits. As illustrated, the command/address (CA) input circuit 20 may receive a CA signal 100 via a channel 102 (e.g., connection, transmission line, and/or conductive material). An output 104 of the channel 102 may be transmitted to an input 106 of a CA receiver 108. A reference voltage VrCA may be applied to an input 110 of the CA receiver 108. A chip select (CS)-gated enable signal 112 may be used to enable the CA receiver 108. A CS-gated enable signal 114 may be used to enable self-adaptation circuits 116. The self-adaptation circuits 116 may include a number of circuits to obtain adaptive settings for the CA input circuit 20 during the operation of the memory device 10. In some embodiments, the CS-gated enable signal 112 and the CS-gated enable signal 114 may be the same signal. In some embodiments, the CS-gated enable signals (e.g., the CS-gated enable signals 112 and 114) may be used to enable corresponding receiver(s) (e.g., the CA receiver 108) and self-adaptation circuits (e.g., the self-adaptation circuits 116) routinely or on demand (e.g., when the distortion of the signals is determined to be greater than a threshold). In some embodiments, the CS-gated enable signals (e.g., the CS-gated enable signals 112 and 114) may be used to enable corresponding receiver(s) (e.g., the CA receiver 108) and self-adaptation circuits (e.g., the self-adaptation circuits 116) anytime when there is data on the command/address bus. In some embodiments, the CS-gated enable signals (e.g., the CS-gated enable signals 112 and 114) may utilize the CS_n signal and enable corresponding receiver(s) (e.g., the CA receiver 108) and self-adaptation circuits (e.g., the self-adaptation circuits 116) for the selected memory chip. For simplicity, the CS-gated enable signal 112 and the CS-gated enable signal 114 may be used in receivers and the self-adaptation circuits (e.g., error latch, bit counters) in all embodiments illustrated below and may not be shown in the figures (e.g., FIG. 3 and FIG. 5). The output 104 of the channel 102 may also be transmitted to the self-adaptation circuits 116 via a path 118. Although a CA receiver is used in the embodiment illustrated in FIG. 2, in some embodiments, receivers for other signals (e.g., CS, CLK_t/CLK_c, CAI, MIR, TEN, CA_ODT, RESET, ALERT) may be used with self-adaptation circuitry to obtain corresponding adaptive settings.

FIG. 3 is a block diagram illustrating an embodiment of a portion of the CA input circuit 20 having self-adaptation circuits 119 that may be used to obtain the adaptive settings. In FIG. 3, an optional pre-amplifier (pre-amp) 105 may be placed in front of the CA receiver 108 to obtain an amplified output 104. Using the optional pre-amp 105 may improve the amplitude of the CA signal from the output 104 and avoid an increase in pad capacitance. In some embodiments, the pre-amp 105 may not be used for power conservation and/or AE. The output 104 together with the reference voltage VrCA may be input into the optional pre-amplifier 105, and the amplified output 104 from the optional pre-amplifier 105 may be transmitted to the input 106 of the CA receiver 108. The CA receiver 108 may include a comparator to receive the CA signal of the output 104 (or the amplified output 104 from the optional pre-amplifier 105) through the input 106. The comparator 120 may receive the reference voltage VrCA through the input 110. The comparator 120 may have an output 122 to transmit a decision code (dₖ) based on the values of the input 106 and the reference voltage VrCA. For example, when the input 106 has a value larger than the reference voltage VrCA, the decision code dₖ may have a value of “1”; and when the input 106 has a value smaller than the reference voltage VrCA, the decision code dₖ may have a value of “0”.

The CA signal of the output 104 (or the amplified output 104 from the optional pre-amplifier 105) may also be transmitted through the path 118 to the self-adaptation circuits 119. The self-adaptation circuits 119 may include an error circuit 130 (e.g., an error latch), which may include a comparator 132. The path 118 may be coupled to an input 134 of the comparator 132, and a programmable reference voltage level (“dLev”) may be applied to an input 136 of the comparator 132. The comparator 132 may transmit an error code (eₖ), which is generated based on the values of the input 134 and the value of the dLev at the input 136, via a path 138. For example, when the input 134 has a value larger than the value of the dLev at the input 136, the error code ex may have a value of “1”; and when the input 134 has a value smaller than the dLev at the input 136, the error code eₖ may have a value of “0”.

The self-adaptation circuits 119 may include a bit counters block 140 to receive the decision code dₖ from the CA receiver 108 via the output 122, and the bit counters block 140 may also receive the error code eₖ from the error circuit 130 via the path 138. The bit counters block 140 is used to perform digital averaging based on the decision code dₖ and the error code eₖ, as described in detail in FIG. 4.

FIG. 4 is a block diagram illustrating an embodiment of the bit counters block 140 that may be used in the self-adaptation circuits 119. The error code eₖ and the decision code dₖ may be input into a decision circuit 142 (e.g., an AND gate) of the bit counters block 140 to generate a decision bit (e.g., “1” or “0”) for an output 144. The output 144 of the decision circuit 142 may be input into an error bit counter 146, which may be used to count a number of decision bits. For example, the decision circuit 142 may include an AND gate, and when the decision code dₖ has a value of “1”, the output 144 may have a value “1” only when the error code eₖ has a value of “1”. When the decision code di has a value of “0”, both the decision code dₖ and the error code eₖ may be flipped (e.g., by using an inverter) before being transmitted into the bit counters block 140 so that the output 144 may have a value “1” only when the error code eₖ has a value of “0”. The output 148 of the error bit counter 146 may have a high (e.g., “1”) value when N (e.g., N=1, 2, . . . ) bits are counted in the error bit counter 146.

The decision code dₖ may also be input into a CA bit counter 150, which may be used to count a total number of 2N decision codes dₖ transmitted to the bit counters block 140. As mentioned above, in some embodiments, when the decision code dₖ has a value of “0”, the decision code dₖ may be flipped (e.g., by using an inverter) before being transmitted into the bit counters block 140. The output 152 of the CA bit counter 150 may have a high (e.g., “1”) value when 2N bits are counted in the CA bit counter 150. The output 152 may be used to stop counting in the error bit counter 146 when 2N bits of decision codes dₖ are counted in the CA bit counter 150. If the error bit counter 146 is stopped before N bits are counted in the error bit counter 146, the output 148 may have a low (e.g., “0”) value. For example, when at least N bits of the 2N bits of decision codes dₖ transmitted into the bit counters block 140 are equal to the corresponding error codes eₖ transmitted into the bit counters block 140, the output 148 may have a value of “1”, which may be used for increment decision. When the output 148 has a value of “0”, no increment decision may be made. The error bit counter 146 may stop counting when 2N bits of decision codes dₖ are received at the CA bit counter 150. Since the value of the output 148 may be determined based on a decision whether the error code eₖ and the decision code dₖ are equal for at least half of the received CA bits (e.g., ≥N of 2N bits), sometimes, the error bit counter 146 may be called decision counter.

Turning back to FIG. 3, the output 148 may be input into a digital logic block 160, which may be used to obtain updated dLev digital code by incrementing or decrementing the current dLev digital code by a step size based on the output 148 of the decision counter 146. The step size may be determined based on the CA input, the historical values of dLev, etc. The digital logic block 160 may include any kind of logic circuits. For example, the digital logic block 160 may include adder/subtractor circuitry to calculate the increment/decrement decision. The output of the digital logic block 160 may be input into a dLev and equalization (EQ) parameter generators block 170, which may be used to generate updated dLev and EQ parameters based on the updated dLev digital code obtained by the digital logic block 160. The output 180 of the dLev and EQ parameter generators block 170 may include the updated dLev and EQ parameters, which may be applied to the error circuit 130 (e.g., the comparator 132) and the CA receiver 108 (e.g., the CA receiver 108 may include a DFE circuit or a CTLE circuit that is used to mitigate the distortion of the CA signals).

For instance, the adaptive values of the input voltage at high level (V_{IH}) and the input voltage at low level (V_{IL}) for inputs may be determined by using the systems and methods described herein. For example, the programmable reference voltage level dLev may be used to determine the adaptive settings for the input voltage levels V_{IH} and V_{IL}. In FIG. 3, the self-adaptation circuits 119 may be used to determine the voltage levels of the V_{IH} and V_{IL} one by one, i.e., one voltage level at a time. For example, the adaptive setting for V_{IH} (or V_{IL}) may be determined first by adjusting the dLev values using the bit counters 140, the digital logic block 160, and the dLev and EQ generators 170, then the adaptive setting for V_{IL} (or V_{IH}) may be determined similarly.

In some embodiments, two error latches may be used in the error circuit of the self-adaptation circuits, as illustrated in FIG. 5. When two error latches are used in the error circuit of the self-adaptation circuits, adaptive settings for two parameters (e.g., the input voltage levels V_{IH} and V_{IL}) may be determined simultaneously. FIG. 5 is a block diagram illustrating another embodiment of a portion of the CA input circuit 20 having self-adaptation circuits 200 that may be used to obtain adaptive settings for two parameters simultaneously. The self-adaptation circuits 200 may have an error circuit 190 including two error latches. For example, the error circuit 190 may include an error latch including the comparator 132 using a programable reference voltage level dLevLo and an error latch including a comparator 192 using a programable reference voltage level dLevHi.

In FIG. 5, the path 118 may be coupled to the input 134 of the comparator 132, and the programmable reference voltage level dLevLo may be applied to the input 136 of the comparator 132. The comparator 132 may transmit an error code (e_{kLo}), which is generated based on the values of the input 134 and the value of the dLevLo at the input 136, via the path 138. For example, when the input 134 has a value larger than the value of the dLevLo at the input 136, the error code e_{kLo} may have a value of “1”; and when the input 134 has a value smaller than the dLevLo at the input 136, the error code e_{kLo} may have a value of “0”.

In addition, the path 118 may be coupled to an input 194 of the comparator 192, and the programmable reference voltage level dLevHi may be applied to an input 196 of the comparator 192. The comparator 192 may transmit an error code (e_{kHi}), which is generated based on the values of the input 194 and the value of the dLevHi at the input 196, via a path 198. For example, when the input 194 has a value larger than the value of the dLevHi at the input 196, the error code e_{kHi} may have a value of “1”; and when the input 194 has a value smaller than the dLevHi at the input 196, the error code e_{kHi} may have a value of “0”.

The bit counters block 140 may receive the error code e_{kHi} from the comparator 192 via the path 198 and the error code e_{kLo} from the comparator 132 via the path 138. The bit counters block 140 may be used to perform digital averaging for the decision code dₖ based on the error code e_{kHi} and the error code e_{kLo}. In some embodiments, a common error bit counter (e.g., the error bit counter 146) may be used in the bit counters block 140 for error bit counting for different values of the decision code dₖ, and a selection device (e.g., a multiplexer) may be used to select the error code e_{kLo} or the error code e_{kHi} to be output to the bit counters block 140 depending on the value of the decision code dₖ. For example, when the decision code dₖ has a value of 0, which means that the CA input at the input 106 of the CA receiver 108 is lower than the reference voltage VrCA, the error code e_{kLo} may be output to the bit counters block 140 (e.g., via the path 138) to determine the increment for the adaptive setting of the dLevLo, and the bit counts in the CA bit counter 150 may be incremented only when the decision code di has a value of 0 (e.g., when the decision code dₖ has a value of “0”, the decision code dₖ and the error code e_{kLo} may be flipped (e.g., by using an inverter) before being transmitted into the bit counters block 140). When the decision code dₖ has a value of 1, which means that the CA input at the input 106 of the CA receiver 108 is higher than the reference voltage VrCA, the error code e_{kHi} may be output to the bit counters block 140 (e.g., via the path 198) to determine the increment for the adaptive setting of the dLevHi, and the bit counts in the CA bit counter 150 may be incremented only when the decision code dₖ has a value of 1. In some embodiments, an additional bit counters block may be used to simultaneously determine the increments for the adaptive settings of the dLevLo and the dLevHi. For example, one bit counters block may be used for the decision code dₖ having a value of 1, and the other bit counters block may be used for the decision code dₖ having a value of 0.

The increment decisions may be transmitted from the bit counters block 140 to the digital logic block 160 via the output 148. The digital logic block 160 may include logic circuits to obtain corresponding adaptive settings (e.g., for the dLevLo and the dLevHi) based on the increment decisions of the bit counters block 140. The output of the digital logic block 160 may be input into the dLev and equalization (EQ) parameter generators block 170, which may be used to generate updated dLevHi, dLevLo, and EQ parameters based on the increment decisions of the bit counters block 140. The output 180 of the dLev and EQ parameter generators block 170 may include the updated dLevHi, dLevLo, and EQ parameters, which may be applied to the error circuit 190 (e.g., the comparator 132 and the comparator 192) and the CA receiver 108 (e.g., the CA receiver 108 may include a DFE circuit or a CTLE circuit that is used to mitigate the distortion of the CA signals).

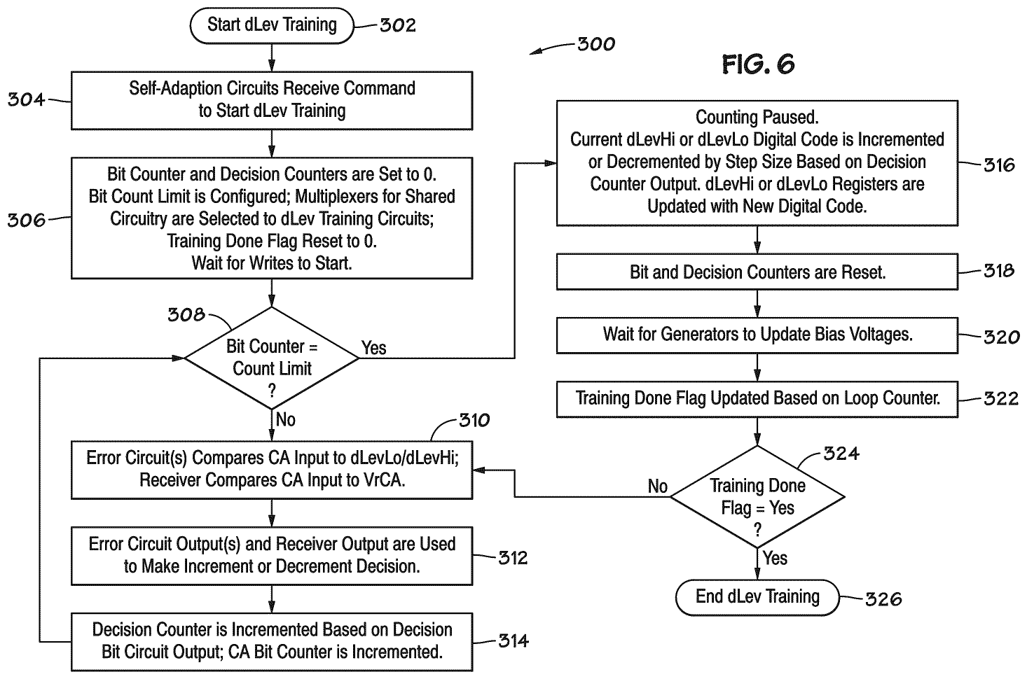

FIG. 6 illustrates a flow diagram of a method 300 for implementing the self-adaptation circuits (e.g., the self-adaptation circuits 119, the self-adaptation circuits 200) for dLev training to determine the adaptive settings for the programmable reference voltage levels (e.g., dLevHi and/or dLevLo). At block 302, the CA input circuit 20 may receive a signal indicating that the dLev training may be started. For example, the memory device 10 may perform the self-adaptation routinely, or on demand (e.g., when the distortion of the signals is determined to be greater than a threshold), or anytime when there is data on the command/address bus, by sending out a self-adaptation signal. At block 304, the self-adaptation circuits 116 may receive the command (e.g., the self-adaptation signal sent from the memory device 10) to start the dLev training, and corresponding CS-gated enable signal(s) (e.g., the CS-gated enable signal 112, the CS-gated enable signal 114) may be used to enable the corresponding circuits (e.g., the CA receiver 108, the self-adaptation circuits 116) for a selected memory chip (e.g., the memory chip 23). In some embodiments, the self-adaptation circuits 116 may include only one error latch (e.g., the self-adaptation circuits 119), and the method 300 may be used to determine the voltage levels of the V_{IH} and V_{IL} one by one, i.e., one voltage level at a time. In some embodiments, the self-adaptation circuits 116 may include two error latches (e.g., the self-adaptation circuits 200), and the voltage levels V_{IH} and V_{IL} may be determined simultaneously by using the method 300. At block 306, the bit counters (e.g., the CA bit counter 150) and the decision counters (e.g., the error bit counter 146) of the self-adaptation circuits (e.g., the self-adaptation circuits 119, the self-adaptation circuits 200) may be set to 0, and the bit count limit (e.g., 2N) may be determined. In some embodiments, selection devices (e.g., multiplexers) may be used to select the self-adaptation circuits (e.g., the self-adaptation circuits 119, the self-adaptation circuits 200) from shared circuitry for dLev training. A training done flag may be used to indicate whether the dLev training is finished, and it may be reset to 0 at block 306. A command, which may be initiated by an internal state machine in the selected memory chip (e.g., the memory chip 23), may be used to start the dLev training. In some embodiments, the command may be triggered every time the selected memory chip is enabled (e.g., by the CS_n signal), while in other embodiments, the command may be triggered based on an oscillator/timer, or a drift in temperature is detected by the temperature sensors, or a drift in voltage is detected, etc.

At block 308, the bit count of the bit counter (e.g., the CA bit counter 150) is determined. If the bit count is less than the bit count limit (e.g., 2N), at block 310, the error circuits (e.g., the error circuit 130, the error circuit 190) may compare the CA input to current values of dLevHi and/or dLevLo (e.g., values of dLevHi and/or dLevLo stored in registers), as described above in the paragraphs regarding FIG. 3 and FIG. 5. At block 310, the CA receiver 108 may compare the CA input to the reference voltage VrCA. Depending on the output of the CA receiver 108 (the value of the decision code dₖ), a selection device (e.g., a multiplexer) may be used to select the error code e_{kLo} or the error code e_{kHi} to be output to the bit counters block 140 for determining the adaptive settings of dLevLo or dLevHi, as described above in the paragraphs regarding FIG. 5. In some embodiments, the adaptive settings of dLevLo and dLevHi may be determined simultaneously, as described above in the paragraphs regarding FIG. 5. At block 312, the output of the decision circuit 142 and the output of the CA receiver 108 (the value of the decision code dₖ) may be used to make increment or decrement decision (e.g., based on a truth table). At block 314, the decision counter 146 may be incremented based on the output 144 of the decision circuit 142, and the CA bit counter 150 may be incremented. Then the block 308 may be repeated, and, if the bit count is determined to be less than the bit count limit (e.g., 2N), the blocks 310 to 314 may be repeated.

If the bit count is determined to be equal to the bit count limit (e.g., 2N) at block 308, the counting of the bit counters block 140 may be paused at block 316. Current dLevHi and/or dLevLo digital codes may be incremented or decremented by a step size based on the output 148 of the decision counter 146. The step size may be determined based on the CA input, the historical values of dLevHi and dLevLo, etc. The dLevHi and dLevLo digital codes may be stored in registers, and the corresponding registers may be updated with the updated dLevHi and/or dLevLo digital codes. At block 318, the CA bit counters (e.g., the CA bit counter 150) and the decision counters (e.g., the decision counter146) may be reset. At block 320, the dLev and EQ generators block 170 may generate updated values for dLevHi and dLevLo based on the updated dLevHi and dLevLo digital codes. At block 322, the training done flag may be updated (e.g., based on a loop counter). At block 324, the value of the training done flag may be determined. If the value of the training done flag satisfies a condition (e.g., equal to a predefined value), the dLev training may be finished at block 326, otherwise, the block 310 may be repeated.

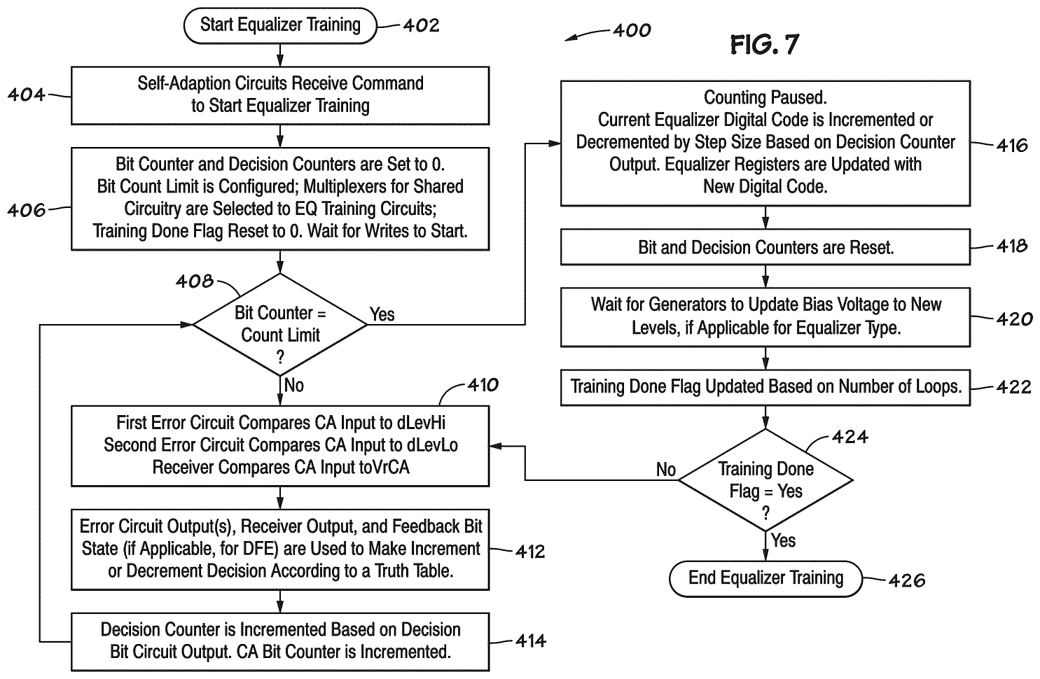

FIG. 7 illustrates a flow diagram of a method 400 for implementing the self-adaptation circuits (e.g., the self-adaptation circuits 116, the self-adaptation circuits 200) for equalizer training to determine the adaptive settings for EQ parameters. At block 402, the CA input circuit 20 may receive a signal indicating that the equalizer training may be started. For example, the signal may be sent after the dLev training is finished, e.g., indicated by the training done flag. At block 404, the self-adaptation circuits 116 may receive a command to start the equalizer training, and corresponding CS-gated enable signal(s) (e.g., the CS-gated enable signal 112, the CS-gated enable signal 114) may be used to enable the corresponding circuits (e.g., the CA receiver 108, the self-adaptation circuits 116) for a selected memory chip (e.g., the memory chip 23). At block 406, the bit counters (e.g., the CA bit counter 150) and the decision counters (e.g., the error bit counter 146) of the self-adaptation circuits (e.g., the self-adaptation circuits 119, the self-adaptation circuits 200) may be set to 0, and the bit count limit (e.g., 2N) may be determined. In some embodiments, selection devices (e.g., multiplexers) may be used to select the self-adaptation circuits (e.g., the self-adaptation circuits 119, the self-adaptation circuits 200) from shared circuitry for equalizer training. A training done flag may be used to indicate whether the equalizer training is finished, and it may be reset to 0 at block 406. A command, which may be initiated by an internal state machine in the selected memory chip (e.g., the memory chip 23), may be used to start the equalizer training. In some embodiments, the command may be triggered every time the selected memory chip is enabled (e.g., by the CS_n signal), while in other embodiments, the command may be triggered based on an oscillator/timer, or a drift in temperature is detected by the temperature sensors, or a drift in voltage is detected, etc.

At block 408, the bit count of the bit counter (e.g., the CA bit counter 150) is determined. If the bit count is less than the bit count limit (e.g., 2N), at block 410, the error circuits (e.g., the error circuit 190) may compare the CA input to current values of dLevHi and dLevLo (e.g., values of dLevHi and dLevLo stored in registers), as described above in the paragraphs regarding FIG. 5. The current values of dLevHi and dLevLo may be adaptive values determined by using the dLev training method illustrated in FIG. 6. At block 410, the CA receiver 108 may compare the CA input to the reference voltage VrCA. Depending on the output of the CA receiver 108 (the value of the decision code dₖ), a selection device (e.g., a multiplexer) may be used to select the error code e_{kLo} or the error code e_{kHi} to be output to the bit counters block 140. At block 412, the output of the decision circuit 142, the output of the CA receiver 108 (the value of the decision code dₖ), and a feedback bit of EQ parameters may be used to make increment or decrement decision (e.g., based on a truth table). For example, equalization (EQ) parameters (e.g., resistance, capacitance, tap bias coefficients) for a DFE circuit (e.g., 1-tap DFE, multi tap DFE) or a CTLE circuit may be used in the CA receiver 108, and the feedback may be used to obtain the adaptive values of the EQ parameters. At block 414, the decision counter 146 may be incremented based on the output 144 of the decision circuit 142, and the CA bit counter 150 may be incremented. Then the block 408 may be repeated, and, if the bit count is determined to be less than the bit count limit (e.g., 2N), the blocks 410 to 414 may be repeated.

If the bit count is determined to be equal to the bit count limit (e.g., 2N) at block 408, the counting of the bit counters block 140 may be paused at block 416. Current EQ parameter digital codes may be incremented or decremented by a step size based on the output 148 of the decision counter 146. The step size may be determined based on the CA input, the historical values of EQ, etc. The EQ digital codes may be stored in registers, and the corresponding registers may be updated with the updated EQ digital codes. At block 418, the CA bit counters (e.g., the CA bit counter150) and the decision counters (e.g., the decision counter146) may be reset. At block 420, the dLev and EQ generators block 170 may generate updated values for EQ (e.g., bias voltages) for an equalization circuit (e.g., DFE, CTLE) based on the updated EQ digital codes. At block 422, the training done flag may be updated (e.g., based on a loop counter). At block 424, the value of the training done flag may be determined. If the value of the training done flag satisfies a condition (e.g., equal to a predefined value), the equalizer training may be finished at block 426, otherwise, the block 410 may be repeated.

Accordingly, the technical effects of the present disclosure include methods and systems for performing self-adaptation to obtain adaptive settings of circuit parameters for memory chips of the memory device during the operation. Individual adaptive settings of the parameters (e.g., impedance, capacitance, equalization parameters) during operation may be obtained for each of the memory chips in the memory device. The self-adaptation may be performed during the operation of the memory device and may not add training time during boot-up. The self-adaptation may enable equalization adjustment across temperature and voltage drift. In particulate, the self-adaptation of the CA input circuit may improve CA write margin and enable faster speed grades.

It should be understood that logically-equivalent circuitry may be used to implement the systems and methods described above. For example, a logical XOR gate may be replaced via a logically-equivalent combination of NOT gates, AND gates, Inverse NOT gates, OR gates, NAND gates, NOR gates, or the like.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

What is claimed is:

1. A device, comprising:
a receiver configured to receive a signal and generate an output for the signal; and
self-adaptation circuits configured to receive the signal and obtain an adaptive value for a parameter based on the signal and the output for the signal.

2. The device of claim 1, wherein the receiver comprises a command/address receiver.

3. The device of claim 1, wherein a selection signal is used to enable the self-adaption circuits to obtain the adaptive value for the parameter for a memory chip of a plurality memory chips of the device.

4. The device of claim 1, wherein the self-adaptation circuits comprises:
an error circuit configured to generate an error code based on a first comparison between the signal and the parameter;
a decision circuit configured to generate a decision bit based on a second comparison between the error code and the output for the signal from the receiver; and
a decision counter configured to generate a count using the decision bit and generate an output indicating increment or decrement of the parameter based on the count.

5. The device of claim 4, wherein the decision circuit comprises an AND gate.

6. The device of claim 4, wherein the self-adaptation circuits comprises an additional error circuit configured to generate an additional error code for an additional parameter based on a third comparison between the signal and the additional parameter.

7. The device of claim 6, wherein the self-adaptation circuits comprises a selection device to select the error code or the additional error code configured to output to the decision circuit based on the output for the signal.

8. The device of claim 4, wherein the self-adaptation circuits comprises a generator block configured to generate an updated value for the parameter based on the output from the decision counter.

9. A method, comprising:
receiving a signal by a receiver;
generating an output for the signal by the receiver; and
generating an adaptive value for a parameter by self-adaptation circuits based on the signal and the output for the signal, wherein the self-adaptation circuits is configured to:
generate an error code based on a first comparison between the signal and the parameter;
generate a decision bit based on a second comparison between the error code and the output for the signal from the receiver;
generate a count using the decision bit; and
generate an output indicating increment or decrement of the parameter based on the count.

10. The method of claim 9, wherein the receiver comprises a command/address receiver.

11. The method of claim 9, comprising:
receiving a selection signal to enable the self-adaption circuits to obtain the adaptive value for the parameter for a memory chip of a plurality memory chips.

12. The method of claim 9, wherein the decision bit is generated by using an AND gate.

13. The method of claim 9, wherein the self-adaptation circuits is further configured to:
generate an additional error code for an additional parameter based on a third comparison between the signal and the additional parameter.

14. The method of claim 13, wherein the self-adaptation circuits is further configured to:
select the error code or the additional error code to generate the decision bit based on the output for the signal.

15. The method of claim 9, wherein the self-adaptation circuits is further configured to:
generate an updated value for the parameter based on the output indicating increment or decrement of the parameter.

16. Self-adaptation circuits, comprising:
an error circuit configured to generate an error code based on a first comparison between a signal and a parameter, wherein a receiver is configured to receive the signal and generate an output for the signal;
a decision circuit configured to generate a decision bit based on a second comparison between the error code and the output for the signal from the receiver; and
a decision counter configured to generate a count using the decision bit and generate an output indicating increment or decrement of the parameter based on the count.

17. The self-adaptation circuits of claim 16, wherein the receiver comprises a command/address receiver.

18. The self-adaptation circuits of claim 16, wherein the self-adaptation circuits comprises an additional error circuit configured to generate an additional error code for an additional parameter based on a third comparison between the signal and the additional parameter.

19. The self-adaptation circuits of claim 18, wherein the self-adaptation circuits comprises a selection device configured to select the error code or the additional error code to output to the decision circuit to generate the decision bit based on the output for the signal.

20. The self-adaptation circuits of claim 16, wherein the self-adaptation circuits comprises a generator block configured to generate an updated value for the parameter based on the output from the decision counter.
